(19) United States
(12) Patent Application Publication
(10) Pub. No.: US 2008/0209294 A1
(43) Pub. Date: Aug. 28, 2008

(54) BUILT-IN SELF TESTING OF A FLASH MEMORY

(76) Inventors: Hakan Brink, Malmo (SE); Daniel Flinck, Saxtorp (SE); Ola Jonsson, Helsingborg (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/740,314

(22) Filed: Apr. 26, 2007

Related U.S. Application Data
(60) Provisional application No. 60/891,535, filed on Feb. 26, 2007.

(51) Int. Cl. G01R 31/317

(52) U.S. Cl. 714/735

(57) ABSTRACT

The present invention relates to a built-in self test of a flash memory device in a data processing device, particularly a mobile terminal, comprising a flash-memory having a plurality of data blocks, a data block memory for temporarily storing a data block of said data blocks, a CPU and a test memory comprising a stored test program executable by the CPU, wherein the method comprises:
a) fetching data from a first data block of said plurality of data blocks of the flash-memory;
b) storing the fetched data temporarily in the data block memory;
c) fetching a test pattern from the test memory,
d) writing said test pattern into the first data block;
e) reading back the test pattern that was written into the first data block;
f) performing a data block test to see whether the first data block is corrupt or not by comparing the test pattern that was written into the first data block in step d) with the test pattern that was read back in step e)
g) reporting the results of the data block test performed in step f); and
h) restoring the first memory block by writing back the fetched data from the data block memory into the first data block.

### TECHNICAL FIELD

The present invention relates to the field of memories and, more particularly, to built-in self testing of memories, such as flash memories.

### DESCRIPTION OF RELATED ART

Mobile terminals, e.g. mobile telephones, generally include flash memories for storing a program for controlling the operation and function of the mobile terminal. As flash memory devices become more and more complex, test routines for properly and extensively testing the flash memories become important.

The European patent application EP 1 388 788 A1, filed on 08 Aug. 2002 and published on 11 Feb. 2004, discloses a built-in self-test (BIST) circuit for integrated circuits. This document describes a BIST circuit adapted to be embedded in an integrated circuit for testing the integrated circuit, including in particular a collection of addressable elements, for example a semiconductor memory. In particular, the BIST circuit is embedded in an integrated circuit, supposed to include a flash memory. The BIST circuit comprises a general-purpose data processor programmable for executing a test program for testing the integrated circuit. The BIST circuit also comprises an accelerator circuit cooperating with the general-purpose data processor for autonomously conducting test operations on the integrated circuit according to the test program. The accelerator circuit comprises configuration means adapted to be loaded with configuration parameters for adapting the accelerator circuit to the specific type of integrated circuit and the specific type of test program.

As of today, the kind of tests to be conducted necessarily varies from flash memory to flash memory. It has been suggested in the prior art by memory vendors (i.e. memory manufactures) to perform tests of flash memories before the memory is shipped to their customers. For instance, the international PCT application WO2006/081168 A1, filed on 23 Jan. 2006 and published on 03 Aug. 2006, describes an automated test for built-in self test. In this document, a method is discussed for providing programmable test conditions for a built-in self test circuit of a flash memory device. The method comprises providing a BIST interface adapted to adjust a test condition used in a BIST circuit, providing the memory cells of the Flash memory device, and providing the BIST circuit adapted to test the flash memory. The method further comprises communicating with the BIST interface one or more global variables associated with the test condition, adjusting the test condition used by the BIST circuit based on the values represented by the global variables, performing one or more test operations on the flash memory in accordance with the adjusted test condition, and reporting the results of the memory test operations. However, a disadvantage with the method described in this document is that it is primarily intended for production testing of a memory before the memory is shipped to the customers of said flash memories.

Whilst the methods and means of the above-mentioned prior art documents do involve advantages, there still appears to be a need for an alternative method and/or means for testing a flash memory that allows the customers of flash memories to perform a quick and easy post-chip-production testing of the flash memory devices once the flash memory devices have been shipped to the customer. For example, customers of these flash memory devices (e.g. mobile telephone manufactures such as Sony Ericsson Mobile Communications®) would benefit from a quick and easy way of finding out whether a shipped flash memory does work properly or whether it is corrupt, e.g. involves a hardware error. It is with respect to these considerations and others that the present invention has been made. Therefore, it has been a general object of the present invention to provide an alternative method and means for testing of a flash-memory, which allow for an easy and quick post-production check whether a flash-memory is corrupt or not.

### SUMMARY OF THE INVENTION

According to an embodiment of the invention, a method of testing a flash-memory device is provided. The flash-memory device comprises a flash-memory comprising a plurality of data blocks, a data block memory for temporarily storing a data block of said data blocks, a CPU and a test memory comprising a stored test program executable by the CPU. The method comprises the following steps:
a) fetching data from a first data block of said plurality of data blocks of the flash-memory;
b) storing the fetched data temporarily in the data block memory;
c) fetching a test pattern from the test memory,
d) writing said test pattern into the first data block;
e) reading back the test pattern that was written into the first data block;
f) performing a data block test to see whether the first data block is corrupt or not by comparing the test pattern that was written into the first data block in step d) with the test pattern that was read back in step e)
g) reporting the results of the data block test performed in step f); and
h) restoring the first data block by writing back the fetched data from the data block memory into the first data block.

In one embodiment, the method steps are performed in consecutive order from step a) to h).

In one embodiment, the step f) of performing a data block test comprises performing a bit-by-bit comparison of the test pattern that was written into the first data block in step d) with the test pattern that was read back in step e).

In one embodiment, the step f) of performing a data block test comprises determining that the first data block is corrupt when the test pattern that was written into the first data block in step d) is not equal to the test pattern that was read back in step e).

In one embodiment, the step c) of fetching test data from a test memory comprises fetching the test pattern from the test pattern memory, wherein the test memory is incorporated within the flash-memory device.

In one embodiment, the step g) of reporting the results of the data block test comprises loading and storing the results of the data block test in a dedicated test result memory.

In one embodiment, the flash-memory comprises a plurality of N data blocks and the method further comprises performing the steps recited in any of the above-mentioned embodiments for each data block of the plurality of N data blocks until a data block test has been performed for all N data blocks.

According to another embodiment of the invention, a computer program product is provided. The computer program product comprises computer program code means for performing the method according to any of the above-mentioned embodiments when said computer program code means is executed by means of an electronic device having computer capabilities.

According to still another embodiment of the invention, a data processing device is provided. The data processing device comprises a flash-memory device, the flash-memory device comprising a flash-memory having a plurality of data blocks, a data block memory interconnected with said flash-memory for the transfer and storage of a data block from said flash-memory to said data block memory, and a CPU interconnected with said flash-memory and said data block memory and further being configured to fetch, load and execute program code stored in said memories; wherein said flash-memory device further comprises a test memory with a stored test program comprising program code means which make the CPU execute, when loaded in said CPU, a procedure realizing the step of loading said test program from said test memory into said CPU and in response thereto realize a procedure following the steps of:
a) fetching data from a first data block of said plurality of data blocks of the flash-memory;
b) storing the fetched data temporarily in the data block memory;
c) fetching a test pattern from the test memory;
d) writing said test pattern into the first data block;
e) reading back the test pattern that was written into the first data block;
f) performing a data block test to see whether the first data block is corrupt or not by comparing the test pattern that was written into the first data block in step d) with the test pattern that was read back in step e)
g) reporting the results of the data block test; and
h) restoring the first data block by writing back the fetched data from the data block memory into the first data block.

In one embodiment, the data processing device is further devised with program code means which make said CPU, when loaded in said CPU, execute a procedure realizing the method steps according to any of the above-mentioned embodiments.

In one embodiment, the data processing device is used in a mobile terminal.

In one embodiment, the mobile terminal is a mobile telephone.

In one embodiment, the mobile terminal is a terminal from the group comprising a mobile radio terminal, a cellular telephone, a pager, a communicator, a smart phone, a Personal Digital Assistant (PDA), an electronic organizer, a computer, a digital audio player or a digital camera.

Some embodiments of the invention provide a method and/or means, which allow for an easy and quick post-production check whether a flash-memory is corrupt or not. It is an advantage with some embodiments of the invention that data from a data block of the flash-memory can be temporarily preserved in a data block memory while a built-in self test is executed for that data block. This way, it is possible to perform a bitwise built-in self test of the flash memory without risking loosing or destroying the program code of the flash memory. In other words, some embodiments of the invention provide the benefit of enabling the execution of a test on a flash memory device without damaging the content stored in the flash memory device.

### BRIEF DESCRIPTION OF THE DRAWINGS

Further objects, features and advantages of the invention will appear from the following detailed description of embodiments of the invention, wherein embodiments of the invention will be described in more detail with reference to the accompanying drawings, in which:

FIG. 1 illustrates a mobile terminal in which embodiments of the present invention may be implemented and a mobile telecommunications network in which such mobile terminal may operate;

FIG. 2 is a functional block diagram of a flash-memory device according to an embodiment of the invention; and

FIG. 3 is a flowchart of a method of testing the flash-memory device of FIG. 2 in accordance with an embodiment of the invention.

### DETAILED DESCRIPTION OF EMBODIMENTS

Embodiments of the present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. In the following description, for purposes of explanation, specific details are set forth in order to provide a thorough understanding of one or more aspects of the present invention. It may be evident, however, to one skilled in the art that one or more aspects of the present invention may be practiced with a lesser degree of these specific details. In other instances, well-known structures and devices are shown in block diagram form in order to facilitate describing one or more aspects of the present invention.

According to embodiments of the present invention, a self-test protocol may be used for performing a built-in self test of a flash memory. The self-test protocol of embodiments of the present invention is suitably pre-loaded into the flash memory device such that the flash memory device itself incorporates the “built-in self test”. In other words, the flash memory device according to embodiments of the invention is pre-loaded with the self-test protocol to be used for testing of a flash memory incorporated within the flash memory device. The flash memory device itself therefore comprises any useful or necessary information about the test as well as the method for testing the flash memory of the flash memory device. It should be appreciated that the self-test protocol is generally vendor specific and is specifically selected by the vendor to match the flash memory to be tested. Having the self-test protocol pre-loaded into the flash memory device itself has the advantage over known prior art solutions that it enables customers of the flash memory devices themselves to perform a quick and easy testing of flash memories of the flash memory devices when the flash memory devices have been shipped to the customers.

In the flash memory device according to embodiments of the present invention, a stored test program is pre-loaded in a test memory. The test program includes the self-test protocol described above, i.e. any necessary information about the test as well as the method for testing the flash memory of the flash memory device. For example, the stored test program may e.g. include any test pattern, test variables and/or test vectors which are useful and/or necessary for the built-in self test to be performed on the flash memory of the flash memory device. The use and operation of test patterns, test variables and/or test vectors for testing flash memories is known to persons ordinary skilled in the art, e.g. from WO2006/081168 A1, and will therefore not be further explained here. Again, it should be emphasized that the test program may be vendor specific and may have been pre-loaded by the memory vendor into the flash memory device prior to shipping the flash memory device to the customer of said flash memory device. The test program may be communicated to a CPU of the flash memory device. The program code means of the test program make the CPU execute, when loaded into said CPU, a procedure realizing the method according to embodiments of the present invention. The method according to embodiments of the present invention will be described in further detail hereinbelow.

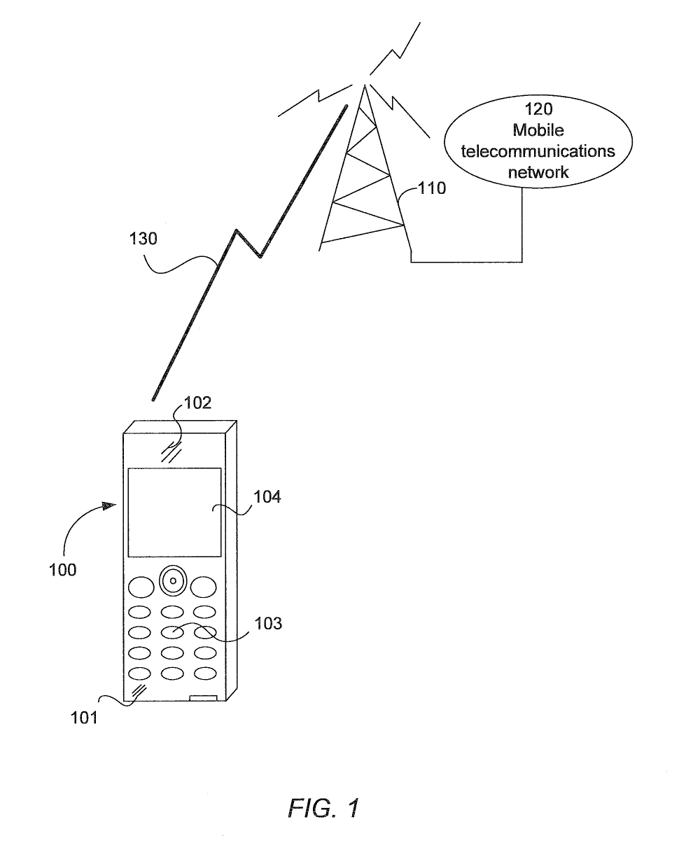

Referring now to FIG. 1, a block diagram illustrating the main functional blocks of a mobile terminal 100 is illustrated. The mobile terminal 100 is illustrated in the form of a mobile telephone, as one exemplifying data processing device in which embodiments of the present invention may be implemented. FIG. 1 also shows a possible environment in which the mobile terminal 100 may operate. The mobile terminal 100 typically comprises an antenna (not shown). A microphone 101, a loudspeaker 102, a keypad 103, and a display 104 provide a man-machine interface for operating the mobile terminal 100. The mobile terminal 100 may in operation be connected to a radio station 110 (base station) of a mobile communication network 120 such as e.g. GSM, UMTS, PCS, and/or DCS network, via a radio link 130. The structure and operation of a mobile telephone as illustrated in FIG. 1 is well-known to persons skilled in the art and will therefore not be further explained here. Besides, embodiments of the invention may be implemented into a wide variety of electronic devices. The electronic device may e.g. be a mobile radio terminal, a pager, a communicator, a smart phone, a Personal Digital Assistant (PDA), an electronic organizer, a computer, a digital audio player such as an MP3-player, a digital camera, etc. Reference will however be to a mobile terminal 100 below, which is only for illustrative purpose and should not be considered as limiting to the embodiments of the invention set forth herein.

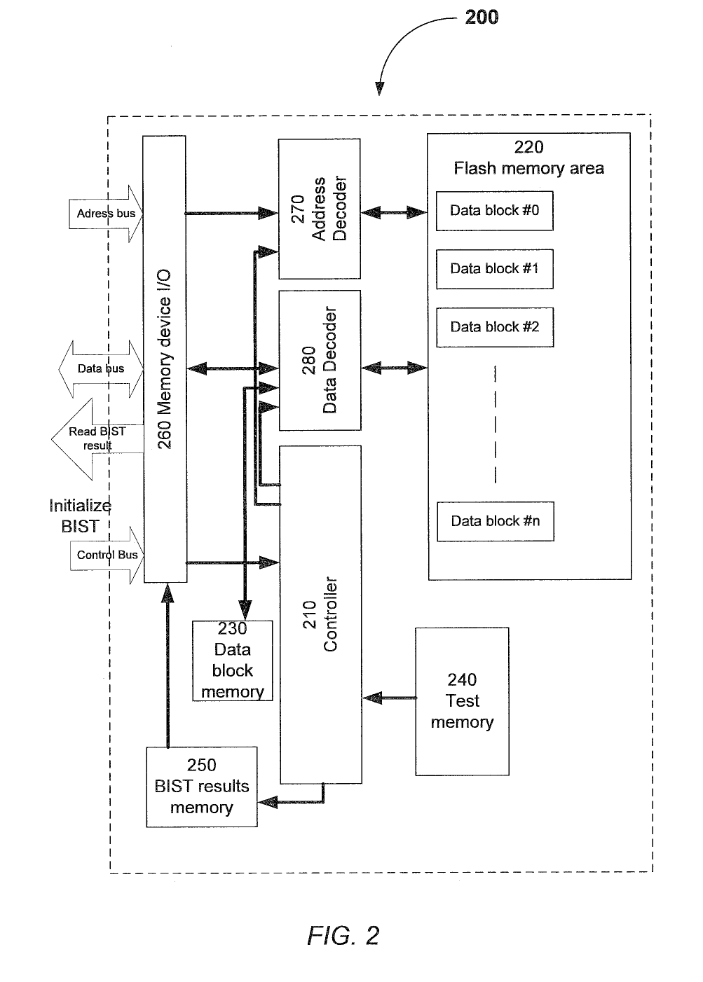

FIG. 2 illustrates a top-view of a flash memory device 200 according to an embodiment of the invention. The flash memory device 200 is incorporated within a data processing device, such as the mobile terminal 100 of FIG. 1. The flash memory device 200 comprises a CPU or controller, 210, e.g. a processor realized in conventional ARM-architecture, and a flash-memory 220. The flash-memory 220 may be any type of flash-memory. For example, the flash-memory 220 may be realized as a NOR-flash-memory or as a NAND-flash-memory. The flash-memory 220 is divided into a plurality data blocks (i.e. Data block #0, Data block #1, Data block #2, . . . , Data block #N) each with a fixed data block size for an efficient execution in said CPU. Each data block may, for example, have a size of 64, 128, 256, or 512 kB. Other block sizes than those mentioned are of course also within the scope of the embodiments of the present invention.

The flash memory device 200 is distinguished from the known prior art in that it further comprises a data block memory 230, the function and operation of which will be described in further detail below. This data block memory 230 may be a volatile memory, e.g. a RAM, a DRAM, eDRAM, SRAM, etc. The flash memory device 200 is also distinguished from the known prior art in that it additionally comprises an internal test memory 240. That is, the test memory 240 is integrated into the flash memory device itself. The test memory 240 may be in the form of a non-volatile memory, e.g. a ROM, PROM, EPROM, or EEPROM, etc. As described earlier, the test memory according to the embodiments of the invention includes a stored test program. Although the test memory is illustrated as one single unit in FIG. 2, it should be appreciated that the test memory 240 could be implemented as e.g. two separate memory units, wherein one memory unit comprises the test variables and the other memory comprises the test pattern for performing the test of the flash memory 220. Furthermore, as is illustrated in FIG. 2, the flash memory device 200 may also comprise a BIST results memory 250 for storing the results of a performed built-in self test (BIST). The BIST results memory 250 may, e.g., be of a flash memory type. Moreover, the flash memory device 200 typically includes input/output circuitry 260 and programming circuitry for selectively addressing the individual data blocks of flash memory 200. The programming circuitry is represented in part by, and includes, one or more decoders (e.g. memory address decoder 270 and memory data recorder 280) that cooperate with the I/O circuitry 260 for selectively connecting an element of selected addresses memory cells of the various data blocks of the flash memory 220 to predetermined voltages or impedances to effect designated operations on the respective memory cells (e.g. programming, reading, erasing, and deriving necessary voltages to effects such operations). As is illustrated by the arrows in FIG. 2, the various components or units of the flash memory device 200 are interconnected with busses. The busses are conventional control-, data- and address-busses enabling the CPU to fetch/store data from/to the memories in a conventional manner.

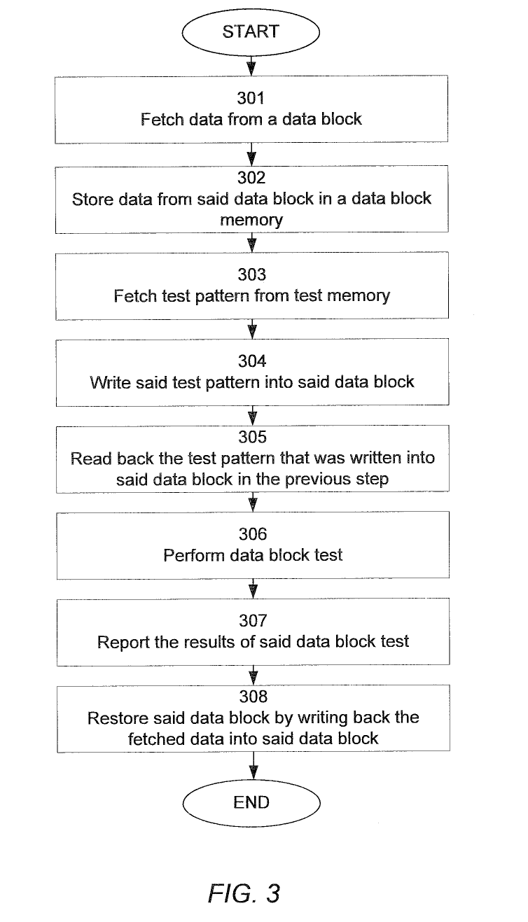

The overall method for realizing and using embodiments of the invention will now be described with reference to FIG. 3. A data processing device, such as mobile terminal 100, comprises the flash-memory device 200 illustrated in FIG. 2. The flash-memory device 200 includes the flash-memory 220 having a plurality of data blocks (i.e. Data block #0, Data block #1 . . . Data block #N), the data block memory 230 interconnected with the flash-memory 220 for the transfer and storage of a data block from said flash-memory 220 to the data block memory 230, and the CPU 210 interconnected with the flash-memory 220 and the data block memory 230 and further being configured to fetch, load and execute program code stored in said memories. The flash-memory device 200 further includes the test memory 240 with the stored test program comprising program code means which make the CPU 210 execute, when loaded into the CPU 210, a procedure realizing the step of loading the test program from the test memory 240 to said CPU. In response thereto, a procedure following three main method steps in accordance with the overall method according to embodiments of the invention is realized, namely: i) temporarily preserving data from a data block of the flash memory 200 within the data block memory 230, ii) while the preserved data is temporarily stored in data block memory 230 performing a test of said data block of the flash memory 220 to see whether that data block is corrupt or not, and iii) restoring said data block by writing back the fetched data from the data block memory 230 into the data block in question as soon as the test in step ii) has been completed. The procedure of method steps i) through iii) may be repeated for all data blocks of the plurality of data blocks of the flash memory 220. Thus, according to embodiments of the invention a block-wise test of the flash memory 220 can be accomplished. By temporarily preserving data from a data block in the data block memory 230 while the test is being executed for that data block makes it possible to perform built-in self tests of the flash memory 220 without risking loosing or destroying the program code of the flash memory 220. Consequently, this overall method allows for performing tests on a flash memory device 200 without damaging the content stored in the flash memory device 200.

In step 301, data from a first data block of a plurality of data blocks of the flash-memory 200 is fetched. In step 302, this fetched data is loaded and stored into the data block memory 230, wherein the fetched data can be stored temporarily. Once the fetched data has been loaded and stored into the data block memory 230, the testing of the first data block of the flash memory 200 can be performed. In this embodiment, the testing involves four steps, i.e. steps 303-306. In step 303, a test pattern is fetched from the test memory 240. Then, in step 304, this fetched test pattern is written into said first data block. Subsequently, in step 305, the test pattern that was written into the first data block is read back. In step 306, a data block test is performed to see whether the first data block is corrupt or not. This step involves comparing the test pattern that was written into the first data block in step 304 with the test pattern that was read back in step 305. For example, this step may comprise a bit-by-bit comparison of the test pattern that was written into the first data block in step 304 with the test pattern that was read back in step 305. If the two test patterns are equal to each other it is concluded that the first data block is working properly. Otherwise, if the two test patterns are not equal to each other it is concluded that the first data block is corrupt in some way. For example, the first data block may be corrupt because of a hardware error. After step 306, the results of the test may be reported in a step 307. This step may involve reporting the result as a simple “passed” and “failed” result for the tested first data block. In some embodiments, the reported results include information about which parts of the first data block that “passed” or “failed”, e.g. which bits are corrupt and which are not. In some embodiments, the results of the data block test may be loaded and stored in a separate test result memory 250 such that these results are available after the test. Finally, in step 308 the first data block is restored by writing back the data that was fetched in step 301 from the data block memory 230 into the first data block of the flash memory 220. In some embodiments, the above-mentioned method steps are performed in consecutive order from step 301-308. However, the method steps of FIG. 3 need not be carried out in the exact order as illustrated in FIG. 3. In fact, in some embodiments of the invention the order of method steps may be different. For example, in some embodiments step 308 could be performed prior to step 307. In a preferred embodiment, the method steps described above are repeated in corresponding manner for all data blocks of the flash memory 220 until a data block test has been performed for each of the data blocks. Preferably, but not necessarily, this is performed in consecutive order starting with a data block test for data block #0, continuing with a data block test for data block #1, continuing with a data block test for data block #2 and so forth until a final data block test has been performed for data block #N.

In the prior art, the memory vendors are focusing and preoccupied with the improvement of their own manufacturing processes of the memory devices. Historically, this has typically involved also the improvement of the memory vendors' own tests and testing methods for the memory devices to be shipped to the customers. Notwithstanding this production testing of the memory devices it may happen that already shipped memory devices indeed be corrupt, e.g. include one or more hardware errors. However, until now there has been no easy and quick post-chip-production solution for the customers of the already shipped memory devices to detect whether these memory devices are corrupt or not. Some embodiments of the present invention thus fulfill a relatively long-felt need among customers of memory devices in that these embodiments of the present invention provide a method and/or means for testing of a flash-memory, which allow for an easy and quick post-chip-production check whether a flash-memory is corrupt or not. It is an advantage with some embodiments of the invention that they allow an easy and quick way of verification and testing of flash memories which can be performed not only by the flash memory vendors themselves but also by their customers after shipping of the flash memories. Thus, the customers of the flash memories may themselves check easily and quickly whether flash memory devices already installed in their products are corrupt or not.

The present invention has been described above with reference to specific embodiments. However, other embodiments than those described are possible within the scope of the invention. For example, while the above embodiments have been discussed primarily with respect to flash memories, it appears to be possible to apply the general principles of these embodiments also to other types of non-volatile memories. Different method steps than those described above, performing the method by hardware or software or a combination of both hardware and software may be provided within the scope of the invention. The different features and method steps of the invention can be combined in other combinations than those described. The invention is only limited by the appended claims.

1. A method of testing a flash-memory device, the flash-memory device having a flash-memory comprising a plurality of data blocks, a data block memory for temporarily storing a data block of said data blocks, a CPU and a test memory comprising a stored test program executable by the CPU, the method comprising the following steps:
a) fetching data from a first data block of said plurality of data blocks of the flash-memory;
b) storing the fetched data temporarily in the data block memory;
c) fetching a test pattern from the test memory,
d) writing said test pattern into the first data block;
e) reading back the test pattern that was written into the first data block;
f) performing a data block test to see whether the first data block is corrupt or not by comparing the test pattern that was written into the first data block in step d) with the test pattern that was read back in step e)
g) reporting the results of the data block test performed in step f); and
h) restoring the first data block by writing back the fetched data from the data block memory into the first data block.

2. The method according to claim 1, wherein the method steps are performed in consecutive order from step a) to h).

3. The method according to claim 1, wherein the step f) of performing a data block test comprises performing a bit-by-bit comparison of the test pattern that was written into the first data block in step d) with the test pattern that was read back in step e).

4. The method according to claim 3, wherein the step f) of performing a data block test comprises determining that the first data block is corrupt when the test pattern that was written into the first data block in step d) is not equal to the test pattern that was read back in step e).

5. The method according to claim 1, wherein the step c) of fetching test data from a test memory comprises fetching the test pattern from the test pattern memory, wherein the test memory is incorporated within the flash-memory device.

6. The method according to claim 1, wherein the step g) of reporting the results of the data block test comprises loading and storing the results of the data block test in a dedicated test results memory.

7. The method according to claim 1, wherein the flash-memory comprises a plurality of N data blocks and the method further comprises performing the steps for each data block of the plurality of N data blocks until a data block test has been performed for all N data blocks.

8. A computer program product comprising computer program code means for performing the method according to claim 1 when said computer program code means is executed by means of an electronic device having computer capabilities.

9. A data processing device comprising a flash-memory device, the flash-memory device comprising a flash-memory having a plurality of data blocks, a data block memory interconnected with said flash-memory for the transfer and storage of a data block from said flash-memory to said data block memory, and a CPU interconnected with said flash-memory and said data block memory and further being configured to fetch, load and execute program code stored in said memories; wherein said flash-memory device further comprises a test memory with a stored test program comprising program code means which make the CPU execute, when loaded in said CPU, a procedure realizing the step of loading said test program from said test memory into said CPU and in response thereto realize a procedure following the steps of:
a) fetching data from a first data block of said plurality of data blocks of the flash-memory;
b) storing the fetched data temporarily in the data block memory;
c) fetching a test pattern from the test memory;
d) writing said test pattern into the first data block;
e) reading back the test pattern that was written into the first data block;
f) performing a data block test to see whether the first data block is corrupt or not by comparing the test pattern that was written into the first data block in step d) with the test pattern that was read back in step e);
g) reporting the results of the data block test; and
h) restoring the first data block by writing back the fetched data from the data block memory into the first data block.

10. The data processing device according to claim 9, the data processing device further being devised with program code means which make said CPU, when loaded in said CPU, execute a procedure realizing steps a) to h) in consecutive order.

11. The data processing device according to claim 9, wherein the data processing device is used in a mobile terminal.

12. The data processing device according to claim 11, wherein the mobile terminal is a terminal from the group comprising: a mobile radio terminal, a mobile telephone, a cellular telephone, a pager, a communicator, a smart phone, a Personal Digital Assistant (PDA), an electronic organizer, a computer, a digital audio player or a digital camera.

13. The data processing device according to claim 9, the data processing device further being devised with program code means which make said CPU, when loaded in said CPU, execute a procedure realizing the steps wherein the step f) of performing a data block test comprises performing a bit-by-bit comparison of the test pattern that was written into the first data block in step d) with the test pattern that was read back in step e).

14. The data processing device according to claim 9, the data processing device further being devised with program code means which make said CPU, when loaded in said CPU, execute a procedure realizing the steps wherein the step f) of performing a data block test comprises determining that the first data block is corrupt when the test pattern that was written into the first data block in step d) is not equal to the test pattern that was read back in step e).

15. The data processing device according to claim 9, the data processing device further being devised with program code means which make said CPU, when loaded in said CPU, execute a procedure realizing the steps wherein the step c) of fetching test data from a test memory comprises fetching the test pattern from the test pattern memory, wherein the test memory is incorporated within the flash-memory device.

16. The data processing device according to claim 9, the data processing device further being devised with program code means which make said CPU, when loaded in said CPU, execute a procedure realizing the steps wherein the step g) of reporting the results of the data block test comprises loading and storing the results of the data block test in a dedicated test results memory.

17. The data processing device according to claim 9, the data processing device further being devised with program code means which make said CPU, when loaded in said CPU, execute a procedure realizing the steps wherein the flash-memory comprises a plurality of N data blocks and the method further comprises performing the steps for each data block of the plurality of N data blocks until a data block test has been performed for all N data blocks.
